(19) United States
(12) Patent Application Publication
(10) Pub. No.: US 2026/0321946 A1
(43) Pub. Date: Oct. 15, 2026

(54) On-chip Broadband Magnetless Isolator

(71) Applicants: IMEC VZW, Leuven (BE); Katholieke Universiteit Leuven, Leuven (BE)

(72) Inventors: Mael Demarets, Watermael-Boitsfrot (BE); Vadiraj Manjunath Ananthapadmanabha Rao, Ghent (BE); Kristiaan De Greve, Heverlee (BE); Christophe Caloz, Oud-Heverlee (BE)

(21) Appl. No.: 19/569,979

(22) Filed: Mar. 17, 2026

(30) Foreign Application Priority Data
Mar. 20, 2025 (EP) 25164955.4

(51) Int. Cl. H01P 1/36; H03H 7/00

(52) U.S. Cl. CPC H01P 1/36; H03H 7/00

(57) ABSTRACT

The present disclosure relates to an isolator device, which is realized by employing non-reciprocal coupling of electromagnetic modes of a transmission line. A device and method are presented, which enable broadband isolation in a bandwidth of interest. This is achieved by controlling a multitude of controllable impedance elements, which are distributed along a transmission line, to generate a set of impedance modulations in the transmission line, and with the impedance modulations new tones in the electromagnetic waves propagating supported by a first subset of modes in the transmission line. Depending on the direction of propagation of the electromagnetic waves, the new tones may constructively or destructively interfere, respectively leading to or preventing parametric coupling from the first subset of modes to a second subset of modes of the transmission line.

### CROSS-REFERENCE TO RELATED APPLICATIONS

The present application is a non-provisional patent application claiming priority to European Patent Application No. EP 25164955.4, filed Mar. 20, 2025, the contents of which are hereby incorporated by reference.

### FIELD OF THE DISCLOSURE

The present disclosure relates to isolator devices and transmission lines, wherein the transmission lines may be optical waveguides or RF transmission lines. The disclosure is particularly concerned with an isolator device, which is realized by employing non-reciprocal coupling between different electromagnetic modes of a transmission line over a bandwidth of interest.

### BACKGROUND

Non-reciprocal devices are ubiquitous in many technical applications, for example, in microwave circuits for antenna multiplexing, reflection-based amplifiers, or for shielding signal sources from backscattered signals. As an example of non-reciprocal devices, isolator devices are commonly found in microwave amplification chains of cryogenic set-ups for shielding a device-under-test, e.g. a quantum circuit.

Conventionally, isolator devices rely on a ferrite, which is biased by a strong magnetic field to break reciprocity. Because of the ferrite and the magnet used to generate the magnetic field, such isolator devices are bulky, i.e., they typically have a size in the range of tens of millimeters. Consequently, such isolator devices cannot be integrated on a chip. Moreover, the rather large magnetic fields can disturb superconductivity, and hence can deteriorate the performance of superconducting circuits, such as used in quantum computers or other ultra-low noise applications.

Despite a strong research interest, which is caused by the above drawbacks, no compact magnet-less isolator device has yet been presented, which can provide broadband isolation and ultra-low noise performance as required, for instance, in sensitive cryogenic environments like superconducting quantum computers.

### SUMMARY

Therefore, an objective of this disclosure is to provide example embodiments for an integrated, and hence small size, non-reciprocal device, which is usable as an isolator device. The device should avoid the above-mentioned drawbacks. For instance, an objective is to provide a magnet-less device, in order to avoid strong magnetic fields. Another objective is to achieve low dissipation, heating, and noise. Another objective is a large operational bandwidth, i.e., to provide broadband isolation, and compatibility with existing integration flows, for example semiconductor integration, for example CMOS.

These and other objectives are achieved by the example embodiments presented in this disclosure, as described in the independent claims. Further implementations are described in the dependent claims.

A first aspect of this disclosure provides a device for broadband isolation in a bandwidth of interest, the device comprising a transmission line having a set of electromagnetic modes supporting the propagation of electromagnetic waves, the set of electromagnetic modes including a first subset of modes in the bandwidth of interest and a second subset of modes outside of the bandwidth of interest; wherein the transmission line comprises a multitude of controllable impedance elements distributed along the transmission line; and a controller configured to control the controllable impedance elements to generate a set of impedance modulations in the transmission line, the impedance modulations producing new tones in the spectrum of the electromagnetic waves propagating in the transmission line; wherein the controller is configured to control the controllable impedance elements to generate the set of impedance modulations with a particular set of associated phases, such that for a first direction of propagation of electromagnetic waves supported by the first subset of modes of the transmission line, the new tones constructively interfere and lead to parametric coupling from the first subset of modes to the second subset of modes, and for an opposite second direction of propagation of the electromagnetic waves supported by the first subset of modes in the transmission line, the new tones destructively interfere and prevent parametric coupling from the first subset of modes to the second subset of modes; wherein the transmission line is further designed such that the set of electromagnetic modes includes a third subset of modes at lower frequencies than the first and second subsets of modes, and such that a phase mismatch between the third subset of modes and the first and second subsets of modes prevents parametric coupling from the first and second subsets of modes to the third subset of modes.

The spectrum of the electromagnetic waves, which propagate in the transmission line, may comprise a set of “tones”, wherein these tones refer to distinct frequency components present in the propagating electromagnetic waves. The electromagnetic waves may be of a signal, for example comprising noise, transmitted via the transmission line. The impedance modulations in the transmission line distort this signal and produce the “new tones”, i.e., produce new frequency components in the spectrum of the propagating electromagnetic waves. The new tones are new distinct frequency components appearing in the propagating electromagnetic waves. The frequencies of these new tones may depend on the frequencies initially present at the input of the of the line. The new tones also propagate along the transmission line, and may interfere with other new tones generated further down the transmission line, for example, by impedance modulations caused by the next controllable impedance element(s). The interference may be constructive or destructive as described, so as to enhance or suppress the parametric coupling between the different subsets of modes of the transmission line.

A subset of modes may comprise one or more modes. The first subset of modes may include all modes within the bandwidth of interest. The second subset of modes may include modes at higher or lower frequencies than the bandwidth of interest, and the third subset of modes may include modes at lower frequencies than the first and second subsets of modes. The bandwidth of interest may refer to the frequency range over which the device operates efficiently as an isolator device. The bandwidth of interest may be a bandwidth defined by the device's design specifications and application requirements.

Parametric coupling from the first subset of modes to the second subset of modes may mean coupling from a specific mode of the first subset to a specific mode of the second subset.

The controllable impedance elements are part of the transmission line. Since the controllable impedance elements are controllable, they can be modulated over time, and thereby produce the new tones. Each impedance modulation may produce new tones, but it is also possible that some impedance modulations do not produce new tones. Of the multitude of impedance elements, all the impedance elements could be controlled to produce impedance modulations in the transmission line, or only a subset of the impedance elements. The more impedance elements are controlled to produce impedance modulations, the stronger the non-reciprocity or isolation effect may be. Each controllable impedance element could be controlled individually by the controller, but it is also possible that the controller controls a plurality of or even all impedance elements together. Each controllable impedance element may correspond to one unit cell of multiple successively arranged unit cells of the transmission line. The new tones produced in one unit cell of the transmission line propagate from this unit cell to the next unit cell(s), and may be modulated in the next unit cell(s) by further impedance modulations, producing again new tones, and so on. The new tones appear in the spectrum of the electromagnetic waves inside the transmission line.

The controller may be configured to control the controllable impedance elements, for instance via a control signal, and is therefore able to control the frequencies and phases of the modulations and therefore of the new tones. Through the controller, it is possible to engineer the desired interference and non-reciprocal parametric coupling in the transmission line.

As mentioned, the impedance modulations distort the electromagnetic field in the transmission line, and thus produce the new tones. Notably, electromagnetic fields can be decomposed as a series of electromagnetic waves, where each electromagnetic wave can be seen as an excitation of a mode. Whether the electromagnetic field carries information or not is not relevant, so the electromagnetic waves may be a signal and/or noise

The phase mismatch between the third subset of modes and the other two subsets of modes prevents undesired parametric amplification, as will be explained in more detail later.

The device of the first aspect can be built in a compact way, without the bulkiness of the ferrite-based approaches. The device can thus be an integrated circuit, or be part of an integrated circuit. For example a semiconductor integrated circuit. The device is suitable for being manufactured in planar layered integration technologies such as for example CMOS or other similar technologies.

Further, the device enables broadband non-reciprocal electromagnetic signal transmission, and can be used as an isolator device. The isolation properties are enhanced by the suppression of parametric amplification. Strong magnetic fields are not required-the device may be magnet-less- and also no biased transistors are necessary, of which the bias currents would result in resistive dissipation, Joule heating, and thermal noise.

In an implementation of the device, the phase mismatch that prevents the parametric coupling from the first and second subsets of modes to the third subset of modes is a phase shift in the dispersion relation of the transmission line between the first and second subsets of modes and the third subset of modes.

For instance, the phase mismatch may be a frequency gap in the dispersion relation of the transmission line between the first two subsets of modes and the third subset of modes. As a consequence no propagating modes exist in this case for the frequencies in the frequency gap.

In an implementation, the device further comprises a multitude of capacitive and/or inductive elements, which are distributed along and connected to the transmission line, configured to generate the phase mismatch.

In an implementation of the device, the transmission line comprises a multitude of consecutively arranged unit cells, each unit cell comprising an inductive element, which is connected in series with the inductive elements of the other unit cells, and a shunt capacitive element to ground; and the multitude of capacitive and/or inductive elements comprising one of the following: a multitude of shunt inductive elements to ground, wherein each unit cell comprises one shunt inductive element; a plurality of shunt inductive elements to ground, wherein only each unit cell of a subset of the unit cells comprises a shunt inductive element; a multitude of resonant element, wherein each unit cell comprises one resonant element, which is connected in series with the inductive and resonant elements of the other unit cells; a plurality of resonant elements, wherein only each unit cell of a subset of the unit cells comprises a resonant element in series with the inductive elements of the other unit-cells; a multitude of resonant elements, wherein each unit cell comprises one resonant element, which is connected in parallel with the shunt capacitive element to ground; a plurality of resonant element, wherein only each unit cell of a subset of the unit cells comprises a resonant element in parallel with the shunt capacitor to ground.

In an implementation of the device, the parametric coupling from the first subset of modes to the second subset of modes comprises adiabatic mode conversion from the first subset of modes to the second subset of modes.

In an implementation of the device, the multitude of controllable impedance elements comprises more than 100, or more than 500, or more than 2000 controllable impedance elements, which are distributed along the transmission line for enabling an adiabatic mode conversion from the first subset of modes to the second subset of modes.

For instance, there may be 100-200 impedance elements, or 500-1000 impedance elements, or 1000-2000 impedance elements, or 2000-5000 impedance elements, depending for instance on the length of the transmission line.

In an implementation of the device, a distance between adjacent controllable impedance elements of the multitude of controllable impedance elements varies along the transmission line; and/or a size of or an area occupied by a respective controllable impedance element of the multitude of controllable impedance elements varies along the transmission line. This can enable a quasi-adiabatic conversion between the first and second subset of modes.

In an implementation of the device, the multitude of controllable impedance elements comprises one of: superconducting quantum interference devices (SQUIDs) configured to be modulated by a set of external magnetic fluxes as a pump signal; voltage-controlled capacitors (varactors) configured to be modulated by a set of external voltages as a pump signal; Josephson junctions, kinetic inductances, a material with second or third order nonlinearity, or any other nonlinear elements configured to be impedance modulated by a pump signal.

The external magnetic fluxes or external voltages may be considered the pump signal. Generally, a pump signal may carry information, for instance, the specific frequency and phases. Each modulation may have a different phase. The pump signal is different from the input signal to the transmission line (i.e., the electromagnetic waves in the transmission line), and may be provided on an additional transmission line as explained below.

In an implementation of the device, the controller is configured to cause an adiabatic mode conversion from the first subset of modes to the second subset of modes by spatially varying the phase-mismatch and/or the amplitude of the modulations, for example by spatially varying the phase velocity of the pump signal and its coupling to the controllable impedance elements.

In an implementation, the device further comprises an additional transmission line extending next to the transmission line; wherein the multitude of controllable impedance elements are connected to the additional transmission line; and wherein the controller is configured to control the controllable impedance elements by generating a pump signal on the additional transmission line.

The pump signal generated by the controller corresponds to the pump signal mentioned above for the different kinds of controllable impedance elements (SQUIDs, varactors, Josephson junctions, etc.). The pump signal may be supported by and propagate along the additional transmission line. The direction of propagation of the pump signal may be chosen depending on the direction in which the isolation of the device is desired. That is, changing direction of propagation of the pump signal may reverse the non-reciprocal characteristics of the device of the first aspect.

In an implementation of the device, the controller is configured to generate the pump signal on the additional transmission line to modulate a voltage across each of a multitude of varactors being the controllable impedance elements, in order to generate the set of impedance modulations; or the controller is configured to generate the pump signal on the additional transmission line to modulate the magnetic fluxes threading the multitude of SQUIDs being the controllable impedance elements, in order to generate the set of impedance modulations.

In an implementation of the device, the controller is configured to control the controllable impedance elements to generate the set of impedance modulations at a first frequency and with an associated set of phases, to realize non-reciprocal adiabatic conversion between electromagnetic waves supported by the first subset of modes and propagating in the first direction of propagation and electromagnetic waves supported by the second subset of modes and propagating in the same first direction of propagation.

Thus, in the device of the first aspect, non-reciprocal coupling can be achieved between electromagnetic waves that are propagating in the same direction and are supported by different modes of the transmission line.

In an implementation of the device, the electromagnetic waves are RF waves and/or RF noise, or the electromagnetic waves are optical waves or optical noise and the transmission lines are waveguides.

In an implementation of the device, the transmission line is an optical waveguide or a RF transmission line. Optical waveguides are considered a sub-family of the transmission lines in this disclosure. Likewise, RF transmission lines are considered a sub-family of the transmission lines in this disclosure.

The device of the first aspect can thus be realized and used for RF and optical communication applications.

A second aspect of this disclosure provides a method of operating a device for broadband isolation in a bandwidth of interest according to the first aspect or any of its implementation, the method comprising propagating electromagnetic waves supported by the first subset of modes of the transmission line in the first direction or in the opposite second direction; controlling the multitude of controllable impedance elements, which are distributed along the transmission line, to generate the set of impedance modulations in the transmission line; wherein the controllable impedance elements are controlled to generate the set of impedance modulations with a particular set of associated phases, such that for the first direction of propagation of the electromagnetic waves supported by the first subset of modes, the new tones constructively interfere and lead to parametric coupling from the first subset of modes to the second subset of modes, and for the opposite second direction of propagation of the electromagnetic waves supported by the first subset of modes, the new tones destructively interfere and prevent parametric coupling from the first subset of modes to the second subset of modes.

The method of the second aspect may have implementations that correspond to the implementations of the device of the first aspect. The method of the second aspect and its implementations achieve the effects and advantages described above for the device of the first aspect and its implementations.

The device and method of this disclosure solve all the issues mentioned above. In particular, the example embodiments of this disclosure enable non-reciprocal transmission-for implementing an isolator device-while avoiding all of the following: (i) bulky magnets and strong magnetic fields, which prevent conventional non-reciprocal devices from being integrated on-chip and/or with superconducting circuits; (ii) dissipation, heating and noise, inherent to the transistor-based devices; (iii) the dependence on the amplitude inherent to non-reciprocal devices using non-linear media; (iv) the limited operational bandwidth of other existing isolator devices based on modulations and interfering modes.

### BRIEF DESCRIPTION OF THE FIGURES

The above, as well as additional, features will be better understood through the following illustrative and non-limiting detailed description of example embodiments, with reference to the appended drawings.

FIG. 1 shows a device for non-reciprocal transmission according to an exemplary embodiment of this disclosure.

FIG. 2 shows a phase mismatch between modes of the transmission line of the device shown in FIG. 1.

FIG. 3a illustrates non-reciprocal parametric coupling in a device according to an exemplary embodiment of this disclosure.

FIG. 3b illustrates non-reciprocal parametric coupling in a device according to an exemplary embodiment of this disclosure.

FIG. 3c illustrates a dispersion diagram of non-reciprocal parametric coupling in a device according to an exemplary embodiment of this disclosure.

FIG. 4a illustrates a superconducting quantum interference device (SQUID) as an exemplary implementation of the impedance elements of a device according to an exemplary embodiment of this disclosure.

FIG. 4b illustrates a voltage-controlled capacitor (varactor) an exemplary implementation of the impedance elements of a device according to an exemplary embodiment of this disclosure.

FIG. 4c illustrates a nonlinear element as an exemplary implementation of the impedance elements of a device according to an exemplary embodiment of this disclosure.

FIG. 4d illustrates a Josephson junction as an exemplary implementation of the impedance elements of a device according to an exemplary embodiment of this disclosure.

FIG. 5a illustrates an implementation of the impedance elements as SQUIDs, in a device according to an exemplary embodiment of this disclosure.

FIG. 5b illustrates a SQUID, in a device according to an exemplary embodiment of this disclosure.

FIG. 5c illustrates an implementation of the impedance elements as SQUIDs with multiple transmission lines, in a device according to an exemplary embodiment of this disclosure.

FIG. 6a illustrates a varactor, in a device according to an exemplary embodiment of this disclosure.

FIG. 6b illustrates an implementation of the impedance elements as varactors with multiple transmission lines, in a device according to an exemplary embodiment of this disclosure.

FIG. 6c illustrates an implementation of the impedance elements as varactors, in a device according to an exemplary embodiment of this disclosure.

FIG. 7a illustrates energy exchange and amplification in an exemplary modulated transmission line.

FIG. 7b illustrates energy exchange in an exemplary modulated transmission line.

FIG. 7c illustrates energy amplification in an exemplary modulated transmission line.

FIG. 8a illustrates microwave isolation with limited performances due to spurious amplification in an exemplary modulated transmission line.

FIG. 8b illustrates a maximum achievable isolation, according to example embodiments.

FIG. 8c illustrates a dispersion diagram of microwave isolation with limited performances due so spurious amplification in an exemplary modulated transmission line.

FIG. 9a illustrates spurious amplification preventing isolation in an exemplary modulated transmission line.

FIG. 9b illustrates a dispersion diagram of spurious amplification preventing isolation in an exemplary modulated transmission line.

FIG. 9c illustrates parametric amplification of the modes and causing the number of photons in the modes to exponentially grow as they propagate, according to example embodiments.

FIG. 10a illustrates the result of dispersion engineering of a device according to this disclosure.

FIG. 10b illustrates a dispersion relation of the result of dispersion engineering against parametric amplification in an exemplary transmission line of a device according to this disclosure.

FIG. 10c illustrates the result of dispersion engineering against parametric amplification in an exemplary transmission line of a device according to this disclosure.

FIG. 11a illustrates shunt inductors in every unit cell of the transmission line, according to example embodiments.

FIG. 11b illustrates shunt inductor in only every five unit cells of the transmission line, according to example embodiments.

FIG. 11c illustrates a series resonant LC tank in every unit cell, according to example embodiments.

FIG. 12a illustrates the limited isolation bandwidth properties of an exemplary modulated transmission line of a device according to an exemplary embodiment of this disclosure.

FIG. 12b illustrates that signals close to 6 GHz are almost fully depleted after 250 unit cells, according to example embodiments.

FIG. 12c illustrates high isolation in a limited range of frequencies, according to example embodiments.

FIG. 13a illustrates a dispersion diagram of (quasi)adiabatic mode conversion via (quasi)adiabatic flux modulation in an exemplary modulated transmission line of a device according to an exemplary embodiment of this disclosure.

FIG. 13b illustrates a plot (quasi)adiabatic mode conversion via (quasi)adiabatic flux modulation in an exemplary modulated transmission line of a device according to an exemplary embodiment of this disclosure.

FIG. 13c illustrates a further plot of (quasi)adiabatic mode conversion via (quasi)adiabatic flux modulation in an exemplary modulated transmission line of a device according to an exemplary embodiment of this disclosure.

FIG. 13d illustrates another plot of (quasi)adiabatic mode conversion via (quasi)adiabatic flux modulation in an exemplary modulated transmission line of a device according to an exemplary embodiment of this disclosure.

FIG. 14a illustrates (quasi)adiabatic mode conversion in a device according to an exemplary embodiment of this disclosure.

FIG. 14b illustrates (quasi)adiabatic mode conversion in a device according to an exemplary embodiment of this disclosure.

FIG. 15a illustrates a first exemplary embodiment for implementing the (quasi)adiabatic flux modulation.

FIG. 15b illustrates a second exemplary embodiment for implementing the (quasi)adiabatic flux modulation.

FIG. 15c illustrates a third exemplary embodiment for implementing the (quasi)adiabatic flux modulation.

FIG. 16a illustrates broadband microwave isolation through (quasi)adiabatic mode conversion in a device according to an exemplary embodiment of this disclosure.

FIG. 16b further illustrates broadband microwave isolation through (quasi)adiabatic mode conversion in a device according to an exemplary embodiment of this disclosure.

FIG. 17 shows a method for operating a device for broadband isolation according to this disclosure.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

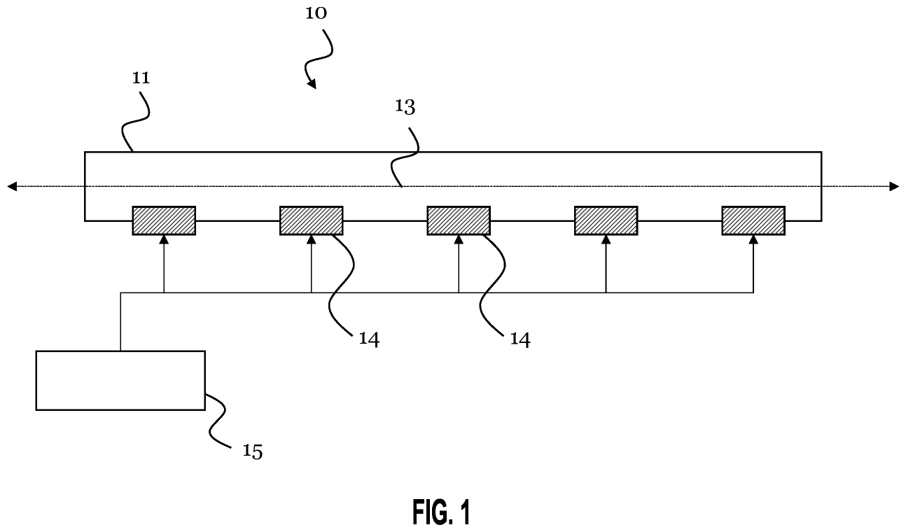

FIG. 1 shows schematically elements of a device 10 according to this disclosure. The device 10 is configured for implementing non-reciprocal signal transmission, wherein the signal is provided by electromagnetic waves 13. Non-reciprocal transmission may mean that a signal transmission between two ports of the device 10 depends on the direction of propagation of the signal. The device 10 shows non-reciprocal properties that allow it to be used as an isolator device. The device 10 is thus suitable for broadband isolation in a bandwidth of interest. The bandwidth of interest may be a bandwidth selected, for instance, based on application requirements of the device 10.

Non-reciprocal transmission in the device 10 of this disclosure means that the electromagnetic waves 13 may propagate efficiently (e.g., with low loss) only in one direction, but not in the opposite direction. For instance, while the electromagnetic waves 13 can pass in the one direction, reflections or other electromagnetic signals are prevented from traveling in the reverse direction. The device 10 has isolation properties in the bandwidth of interest, which may mean a high attenuation (e.g., 20-30 dB) in the reverse direction. The device 10 may have a low insertion loss, which may mean a minimal power loss in the forward direction (e.g., <1 dB). The device 10 of this disclosure is magnet-less.

The device 10 comprises a transmission line 11, which has a set of electromagnetic modes that support the propagation of the electromagnetic waves 13, for example, at a certain phase velocity. The electromagnetic waves 13 may be a signal or noise. The electromagnetic waves 13 may be RF waves or light waves. The set of electromagnetic modes includes a first subset of modes 21 including one or more modes in the bandwidth of interest, and a second subset of modes 22 including one or more modes outside of the bandwidth of interest, for example, at higher frequencies than the bandwidth of interest.

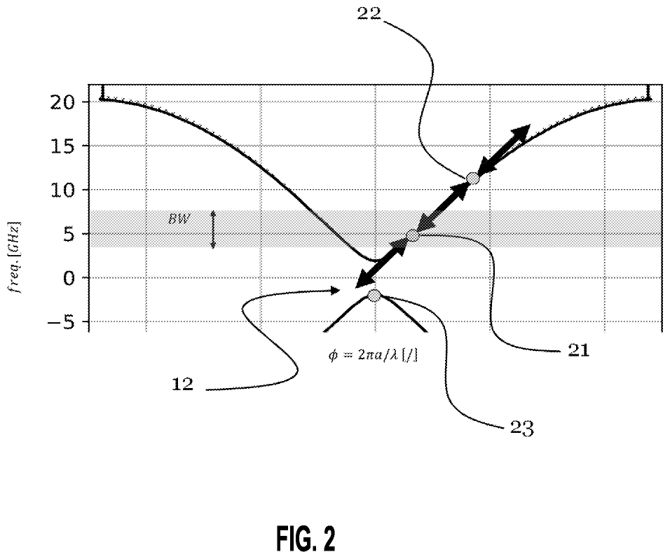

Modes from these two subsets of modes 21, 22 are illustrated in FIG. 2, which generally shows an exemplary dispersion relation of the transmission line 11. The dispersion relation shows how the frequency of the electromagnetic waves 13 varies with its wavelength and their accumulated phase. It describes the allowed frequencies of the transmission line 11 for different wavelength values. That is, the transmission line 11 supports many modes, corresponding to points on the dispersion curve. The modes of the first subset of modes 21 are in the bandwidth of interest on the dispersion curve, and the second subset of modes 22 are outside of the bandwidth of interest on the dispersion curve.

The transmission line 11 is further designed such that the set of electromagnetic modes of the transmission line 11 also include a third subset of modes 23 including one or more modes at lower frequencies than the first and second subsets of modes 21, 22. The transmission line 11 is particularly designed (e.g., it may be dispersion engineered) such that there is a phase mismatch 12 between the third subset of modes 23 and the first and second subsets of modes 21, 22.

The device 10 further comprises a multitude of controllable impedance elements 14, which are part of the transmission line 11 and are arranged or distributed along the transmission line 11. For instance, the impedance elements 14 may be arranged one after the other and/or at regular intervals along the extension direction of the transmission line 11. The impedance elements 14 may all be of the same type.

Further, the device 10 comprises a controller 15, which is configured to control the controllable impedance elements 14. The controller 15 is configured to control the controllable impedance element 14. For instance, the controller 15 may be any unit capable of providing a control signal or pump signal to each of the controllable impedance elements 14. The controller may be a processor, but may also be a voltage or current source. The controller 15 is specifically configured to control the impedance elements 14 such that they generate a set of impedance modulations in the transmission line 11. Each impedance modulation of the set of impedance modulations produces new tones in the spectrum of the electromagnetic waves 13 that propagate in the first transmission line 11. The new tones are new frequencies in the spectrum. Electromagnetic waves 13 in the transmission lines may be signals and/or noise.

The controller 15 is configured to control each controllable impedance element 14 to generate the set of impedance modulations with a particular set of associated phases. Thereby, these associated phases are selected such (e.g., by the controller 15) that the coupling between the first and second subset of modes 21, 22 of the transmission lines differ for different propagation directions of the electromagnetic waves 13. In particular, for a first direction of propagation of electromagnetic waves 13 supported by the first subset of modes 21 of the transmission line 11, the new tones constructively interfere and lead to parametric coupling from the first subset of modes 21 to the second subset of modes 22. For an opposite second direction of propagation of the electromagnetic waves 13 supported by the first subset of modes 21 in the transmission line 11, the new tones destructively interfere and prevent parametric coupling from the first subset of modes 21 to the second subset of modes 22. In this way, non-reciprocal transmission of the electromagnetic waves 13 (e.g. of a signal) through the transmission lines 11 of the device can be achieved in the bandwidth of interest, as the parametric coupling depends on the propagation direction.

FIG. 2 shows that in the forward direction the first subset of modes 21 may parametrically couple to the second subset of modes 22 (energy can be efficiently transferred between these two modes through a parametric process by the impedance modulations, indicated by the arrow connecting the modes of the first and the second subsets 21, 22). Moreover, the phase mismatch 12 is also shown in FIG. 2, and prevents parametric coupling from the first and second subsets of modes 21, 22 to the third subset of modes 23 (e.g., the arrow does not connect the modes of the first and the third subsets of modes 21, 23, i.e., energy cannot be efficiently transferred by the impedance modulations). The phase mismatch 12 maybe a phase shift in the dispersion relation of the transmission line 11 between the first and second subsets of modes 21, 22 and the third subset of modes 23, as illustrated. For instance, it may be a frequency gap. The disclosure is, however, not limited to such examples, other examples are possible for the phase mismatch engineering.

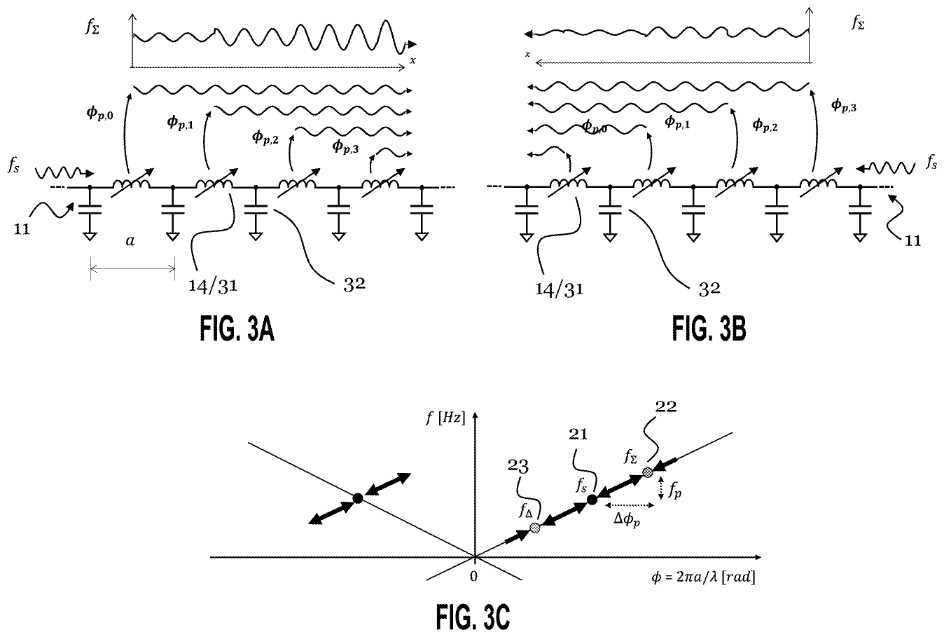

FIG. 3 illustrates in more detail the non-reciprocal parametric coupling between the first and second subset of modes 21, 22 in a device 10 according to an exemplary embodiment of this disclosure.

FIG. 3 shows that in the exemplary device 10, the transmission line 11 comprises a multitude of consecutively arranged unit cells. Each unit cell comprises an inductive element 31, which is connected in series with the inductive elements 31 of the other unit cells, and comprises a shunt capacitive element 32 to ground. The inductance of each inductive element can be tuned (indicated by the arrow), making each inductive element 31 correspond to a controllable impedance element 14.

The multiple impedance modulations, which are produced by the controllable impedance elements 14, each distort the signal—i.e. the spectrum of the electromagnetic waves 13 propagating in the transmission line 11—and produce the series of new tones in the spectrum. By controlling the phases of the impedance modulations, the phases of the new tones can be controlled, and the new tones can be made to interfere constructively as they propagate in the transmission line 11. In the dispersion diagram shown in FIG. 3(c), the modulations are represented by arrow(s). If the modulations have a proper frequency fₚ and associated phases φ_{p,n+1}=φ_{p,n}+Δφₚ, they can couple two modes propagating in the same transmission line 11, but at different frequencies, e.g. at fₛ (mode in the first subset of modes 21) and f_{Σ}=fₛ+fₚ (mode in the second subset of modes 22).

In particular, the phases of the impedance modulations may produce new tones that interfere constructively as they propagate on the transmission line 11 in one direction of propagation (positive phase values on the x-axis), as shown in FIG. 3(a), and may produce new tones that interfere destructively in the reverse direction (negative phase values on the x-axis), as shown in FIG. 3(b), hence realizing non-reciprocal parametric coupling in the transmission line 11. In the dispersion diagram shown in FIG. 3(c), a same modulation, i.e. arrow, cannot couple two modes fₛ and f_{Σ} in both the forward direction (right side of zero) and the backward direction (left side of zero).

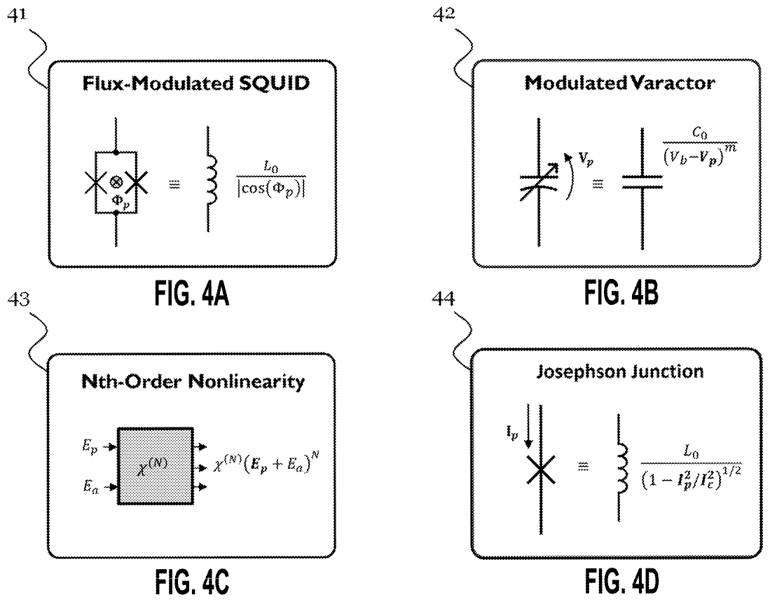

FIG. 4 illustrates exemplary implementations of the controllable impedance elements 14 of a device 10 according to an exemplary embodiment of this disclosure. FIG. 4(a)-(d) particularly shows that the controllable impedance elements 14, which are shown in FIG. 1, may respectively be (a) superconducting quantum interference devices (SQUIDs) 41, which are configured to be modulated by an external flux, or may be (b) voltage-controlled capacitors (varactors) 42, which are configured to be controlled by an external voltage, or may be (d) Josephson junctions 44, or kinetic inductances, or materials with second or third order nonlinearity, or (c) any other nonlinear elements 43 configured to be impedance modulated by a pump signal (e.g., provided by the controller 15).

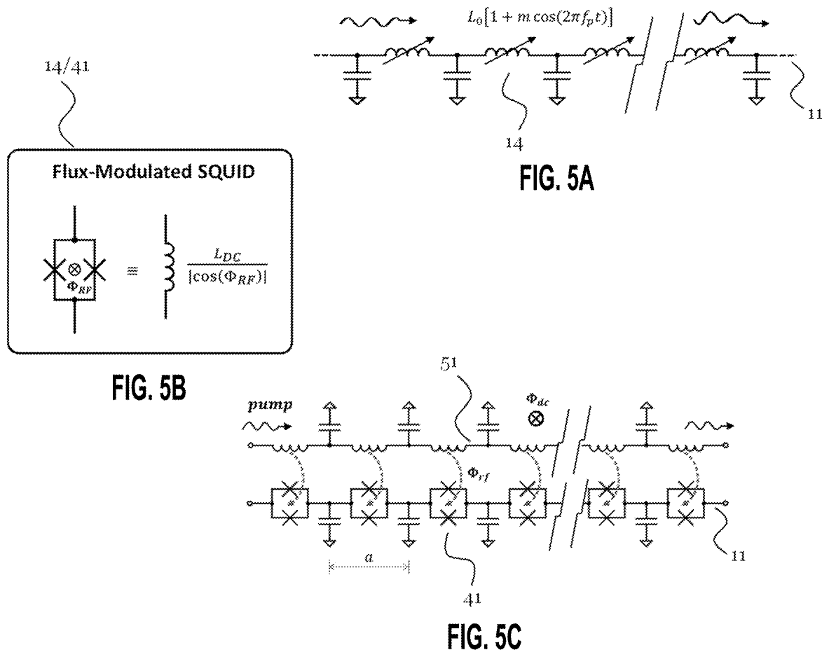

FIG. 5 illustrates an implementation of the controllable impedance elements 14 as SQUIDs 41 (see FIG. 5(b)), in a device 10 according to an exemplary embodiment of this disclosure. The enclosed magnetic flux of the SQUIDs 41 may be modulated by a pump signal propagating on an additional transmission line 51 (see FIGS. 5(a) and (c)), which extends next to the transmission line 11. The controller 15 is configured to generate the pump signal on the additional transmission line 51 to modulate the enclosed magnetic flux of each SQUID 41. If the additional transmission line 51 has the right phase velocity, the pump signal will generate impedance modulations in the transmission line 11, with the adequate set of phases. As mentioned above the propagation direction of the pump signal may be selected according to the desired isolation characteristics of the device 10.

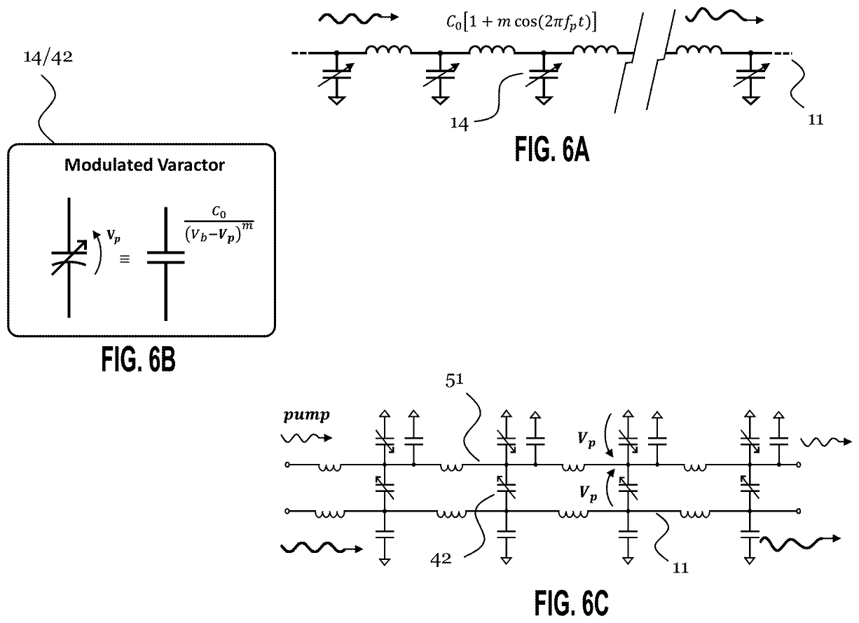

FIG. 6 illustrates an implementation of the controllable impedance elements 14 as varactors 42 (see FIG. 6(b)), in a device 10 according to an exemplary embodiment of this disclosure. The pump signal propagating on the additional transmission line 51 (see FIGS. 6(a) and (c)) may modulate the voltage seen across a varactor, changing its capacitance. The controller 15 is configured to generate the pump signal on the additional transmission line 51 to modulate the voltage across each varactor 42. If the additional transmission line 51 has the right phase velocity, the pump signal will generate impedance modulation sin the transmission line 11, with the adequate set of phases.

Some further explanations regarding the design of the transmission line 11 of the device 10 according to this disclosure are provided in the following.

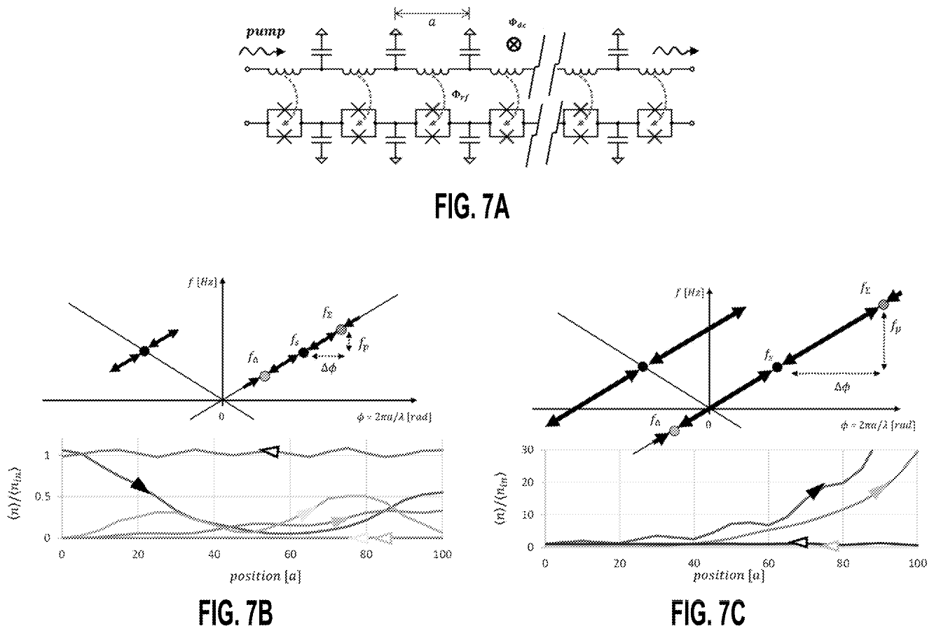

FIG. 7 illustrates energy exchange and amplification in an exemplary modulated transmission line shown in FIG. 7(a). The modulated transmission line with the non-reciprocal parametric coupling could display two different phenomena. With the appropriate modulation frequency and associated phases, non-reciprocal parametric coupling could be used to realize directional conversion of energy between two modes propagating in the transmission line 11 at different frequencies fₛ and f_{Σ/Δ}, as shown in FIG. 7(b). Alternatively, by choosing the appropriate frequency and associated phases, one could realize directional amplification of two modes propagating in the transmission lines 11 at different frequencies fₛ and f_{Δ}, as shown in FIG. 7(c).

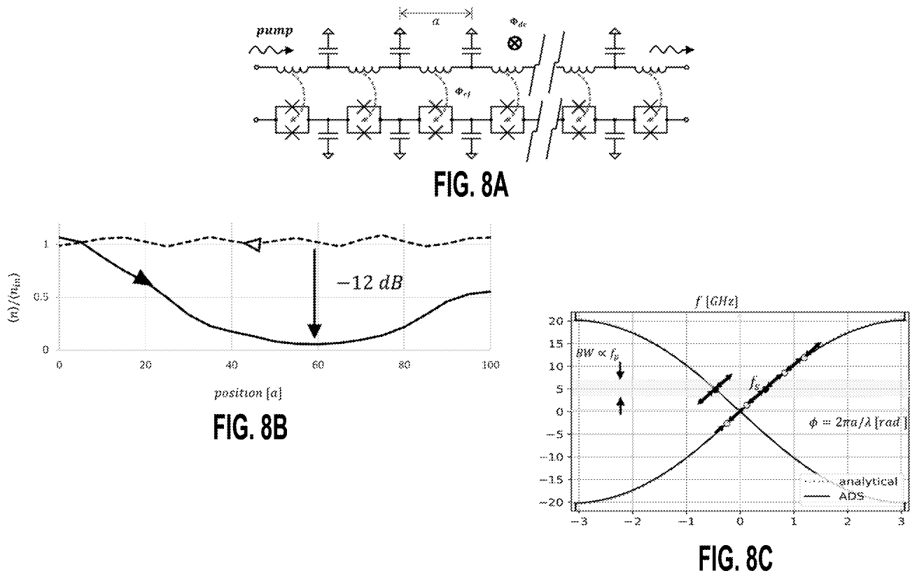

FIG. 8 illustrates microwave isolation in an exemplary modulated transmission line (see FIG. 8(a)). Parametric modulation may be used to realize microwave isolation. With the appropriate modulation frequency and associated phases, directional parametric coupling can be used to convert the energy at frequency fₛ to other modes outside the bandwidth of interest. These modes can then be filtered out, hence providing a direction-dependent attenuation, i.e. isolation. However, the maximum achievable isolation, here −12 dB as shown in FIG. 8(b), may be limited due to spurious amplification occurring at lower frequency modes. This can be solved with dispersion engineering, i.e., by introducing the phase mismatch 12.

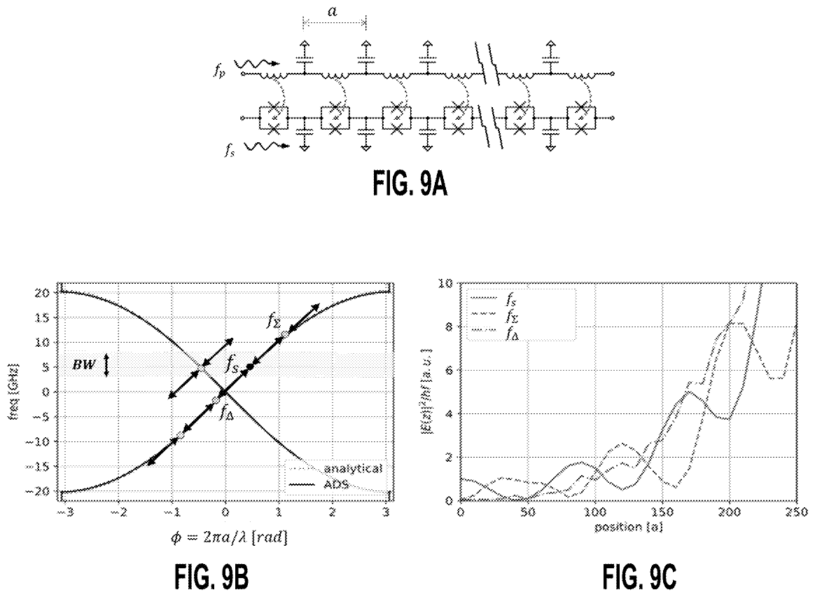

In this respect, FIG. 9 illustrates spurious amplification preventing isolation in an exemplary modulated transmission line (see FIG. 9(a)) without phase mismatch 12. The parametric modulations represented in the dispersion diagram, shown in FIG. 9(b), by the arrows, can result in amplification or mode conversion depending on the frequencies of the coupled modes, i.e. fₚ=fₛ+f_{Δ} or fₚ=|f ₛ−f_{Σ}|, respectively. FIG. 9(c) shows that parametric amplification of the modes fₛ and f_{Δ} causes the number of photons in the modes to exponentially grow as they propagate. Parametric mode conversion results in energy exchange between the coupled modes at frequency fₛ and f_{Σ}. Because of this gain, the mode at f s cannot be depleted and high isolation is not attainable.

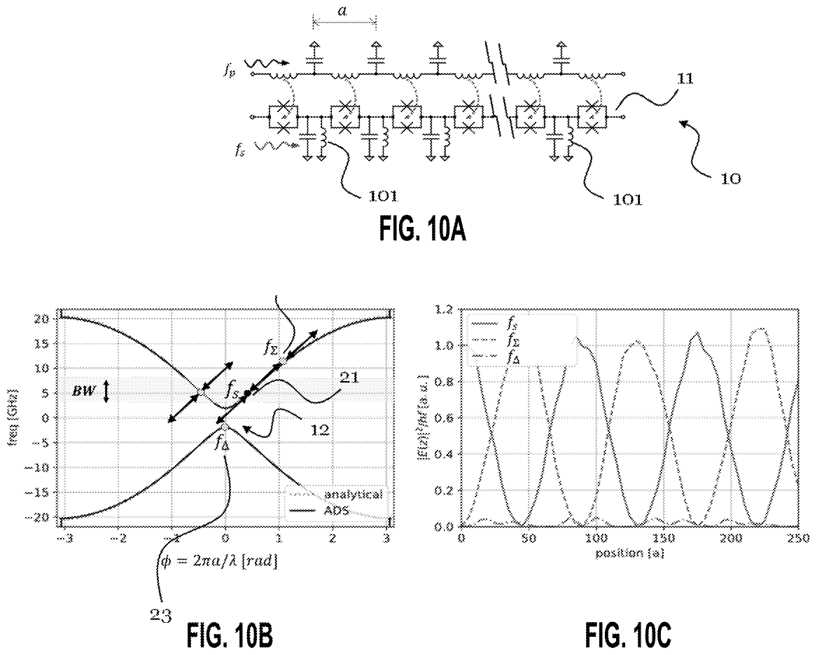

Therefore, as illustrated in FIG. 10, dispersion engineering may be used against the parametric amplification in an exemplary transmission line 11 (see FIG. 10(a)) of a device 10 according to this disclosure. As mentioned previously, in particular, a phase mismatch 12 is used to prevent parametric coupling. As shown in FIG. 10(b), the dispersion relation of the lower frequency modes (modes of the third subset of modes 23) may be engineered to ensure that the parametric modulation is strongly phase-mismatched at these frequencies, resulting in weak parametric coupling and limiting the amplification of these modes. As shown in FIG. 10(c), this dispersion engineering technique prevents parametric amplification, and only parametric conversion remains between the two coupled modes fs (mode of the first subset of modes 21) and fi (mode of the second subset of modes 22).

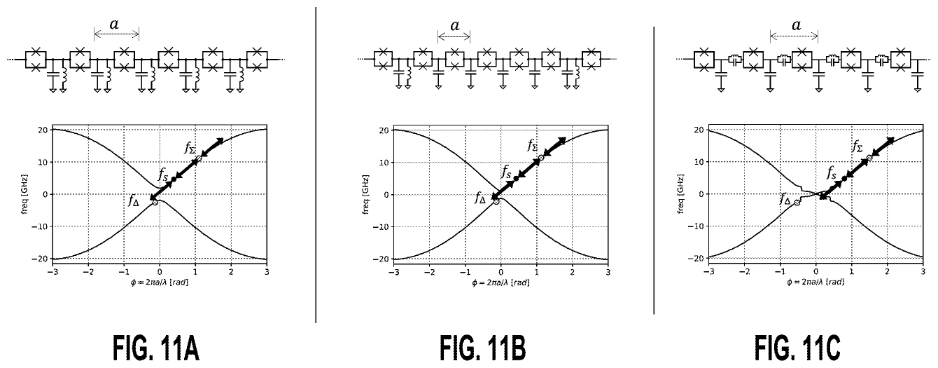

FIG. 11 shows various exemplary embodiments for implementing the dispersion engineering. Engineering of the dispersion relation of the transmission line 11 may be done by periodically adding a combination of capacitive and/or inductive elements 101 to the transmission line 11 (see also FIG. 10(a)). Several examples are illustrated in FIG. 11. In particular, FIG. 11(a) shows that one can use shunt inductors in every unit cell of the transmission line 11 to filter out the lower frequency modes and open a bandgap around DC. FIG. 11(b) shows that as an alternative implementation, one can use a similar shunt inductor in only every five unit cells, so as to open a bandgap around 0 GHz. FIG. 11(c) shows that as a third option, one can use a series resonant LC tank in every unit cell to open a bandgap around 1 GHz. Regardless, every dispersion engineering technique guaranteeing a phase mismatch 12 between the mode f s (first subset of modes 21) and the lower frequency modes (third subset of modes 23) may be used.

In the following, isolation properties of the device 10 according to this disclosure are further discussed.

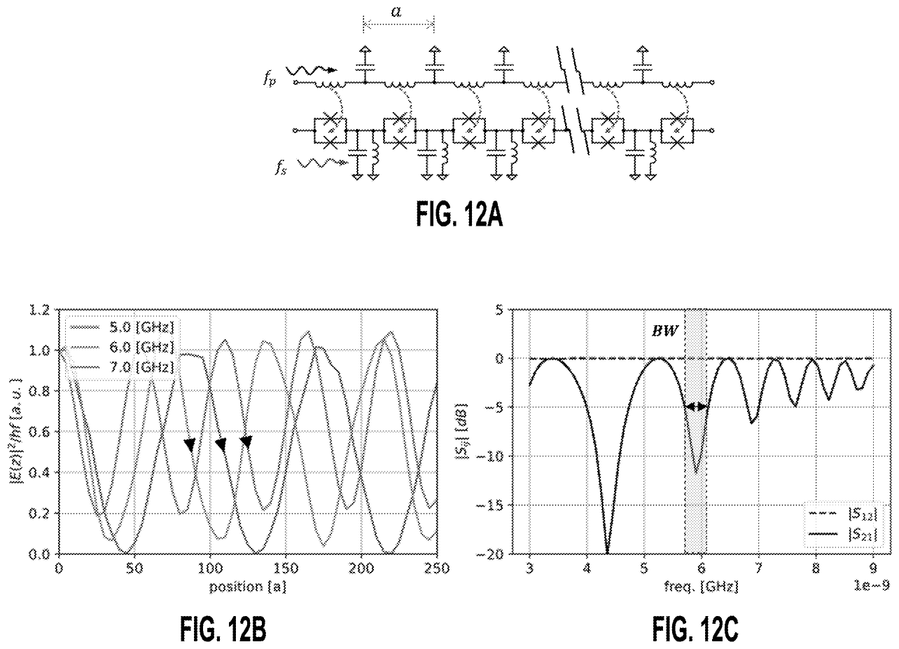

FIG. 12 illustrates in this regard isolation bandwidth properties of an exemplary modulated transmission line 11 (see FIG. 12(a)) according to this disclosure. Maximum isolation may be obtained by tuning the strength of the parametric coupling to deplete the input mode fs (mode of the first subset of modes 21) fully at the end of the transmission line 11. However, an optimal modulation amplitude to fully deplete the input mode depends on the frequency of the mode. FIG. 12(b) shows that signals close to 6 GHz are almost fully depleted after 250 unit cells of the transmission line 11, hence achieving close to −10 dB attenuation. However, signals around 5 GHz are not as attenuated after 250 unit cells of the transmission line 11, and the resulting isolation is closer to −2 dB. FIG. 12(c) shows that an optimal modulation can guarantee high isolation in a limited range of frequencies.

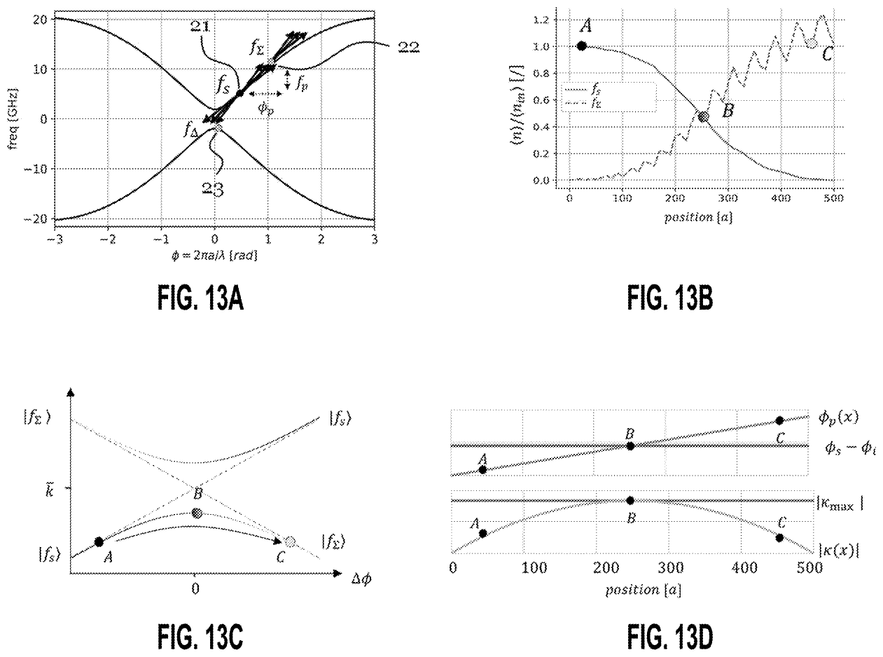

FIG. 13 illustrates (quasi)adiabatic mode conversion via adiabatic modulation in an exemplary modulated transmission line according to this disclosure. The population of one mode of the first subset of modes 21 can be fully converted (see FIG. 13(a)) to a mode of the second subset of modes 22 without back-conversion, as shown in see FIG. 13(b), by adiabatically sweeping the detuning between the two modes. FIG. 13(c) shows that the detuning between two parametrically coupled modes may be controlled through the phase difference Δφ=φᵢ−φₛ−φₚ, and adiabatic conversion can be achieved by spatially varying the phase velocity vₚ=1/\sqrt{LₚCₚ} of the pump signal on the additional transmission line 51, since

$${ϕ}_{p} ( x ) = ω {\int }_{0}^{x} {v}_{p}^{- 1} ( \tilde{x} ) d \tilde{x} .$$

FIG. 13(d) shows that to shorten the required device length, fast quasi adiabatic conversion can be realized by also varying the modulation amplitude the coupling strength such that that the phase mismatch at both ends of the line is much larger than the amplitude of the parametric coupling.

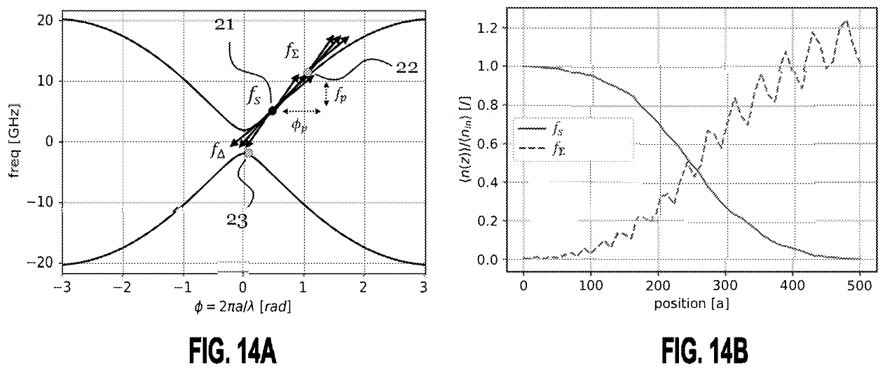

FIG. 14 illustrates further that (quasi-)adiabatic parametric modulation, as explained with respect to FIG. 13, non-reciprocally converts, with no back-conversion, the input signal at frequency fₛ (mode of the first subset of modes 21) to a mode f_{Σ} outside the bandwidth of interest (mode of the second subset of modes 22), where it can be filtered out to provide isolation. Optimization of the modulation is not required making this approach more robust as well.

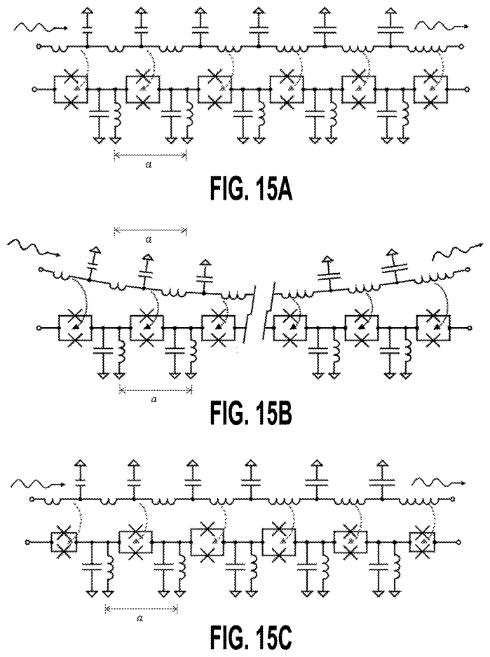

FIG. 15 shows various exemplary embodiments for implementing the adiabatic flux modulation. FIG. 15(a) shows that quasi-adiabatic conversion can be realized by spatially varying the phase velocity of the pump signal only. FIG. 15(c) shows that additionally the flux-modulation amplitude can also be varied by changing the physical distance between SQUIDs 41 (as example of the controllable impedance elements 14) and the pump line. FIG. 15(b) shows that alternatively the distance can be kept constant, but the areas of the SQUIDs 41 may be varied. Both techniques can be combined as well. Each of the above techniques changes the magnetic coupling between flux generated in the additional transmission line by means of the applied pump signal and the SQUIDs 41 thereby achieving the (quasi-)adiabatic coupling.

It should be clear from the above that the (quasi-)adiabatic coupling can also be achieved for the different controllable impedance elements 14 as described before. Although different techniques, known to the skilled person, may be required to achieve it.

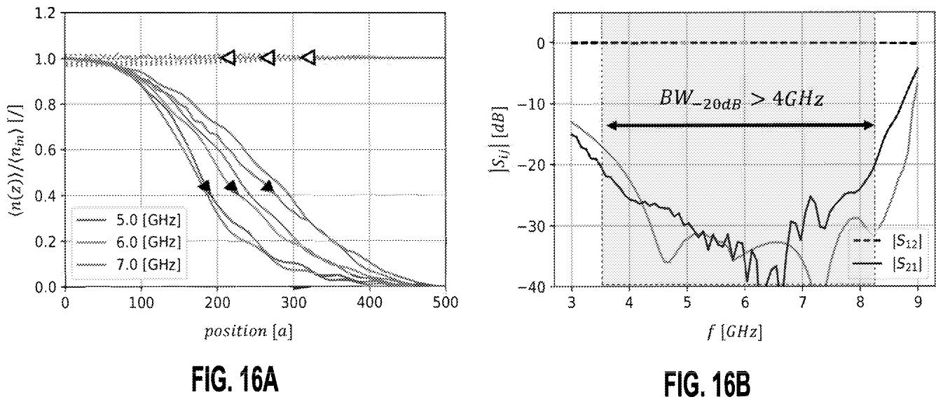

FIG. 16 illustrates broadband microwave isolation through adiabatic mode conversion in an exemplary device 10 according to this disclosure, in particular, with the parametric modulated transmission line 11. Dispersion engineering is employed against spurious amplification, and adiabatic modulation is used for broadband mode conversion. Overall, a broadband on-chip magnet-less isolator device can be obtained.

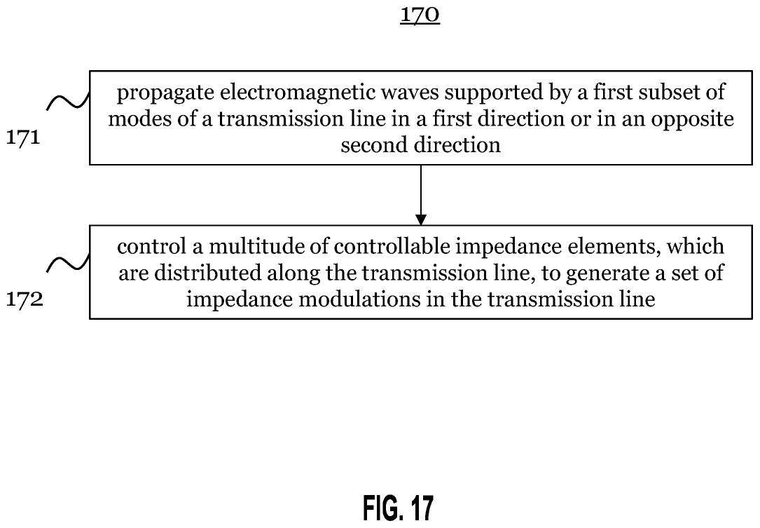

FIG. 17 shows a method 170 according to this disclosure, in particular, a flow diagram of method steps 171 and 172. The method 170 can be carried out to operate a device 10 for broadband isolation, for instance, as illustrated in the previous figures

Step 171 comprises propagating electromagnetic waves (13) supported by the first subset of modes 21 of the transmission line 11 in the first direction or in the opposite second direction.

Step 172 comprises controlling a multitude of tunable impedance elements 14, which are distributed along the transmission line 11, to generate a set of impedance modulations in the transmission line 11. Each impedance modulation of the set produces new tones in the electromagnetic waves 13 propagating in the transmission line. The step 172 can control the tunable impedance element 14 to generate the set of impedance modulations with a particular set of associated phases. The step 172 is thereby carried out such that for a first direction of propagation of the electromagnetic waves 13 supported by a first subset of modes 21 in the first transmission line 11, the new tones in the electromagnetic waves 13 in the first transmission line 11 constructively interfere and lead to parametric coupling from the first subset of modes 21 to the second subset of modes 22, i.e., they couple to the second subset of modes 22 of the transmission line 11. Further, such that for an opposite second direction of propagation of the electromagnetic waves 13 supported by the first subset of mode 21 in the transmission line 11, the new tones of the electromagnetic waves 13 in the transmission line 11 destructively interfere and prevent parametric coupling from the first subset of modes 21 to the second subset of modes 22, i.e., they do not couple to the second subset of modes 22.

In summary, this disclosure presents a device 10 and method 170 relying on an impedance-modulation-induced non-reciprocal parametric coupling of electromagnetic waves 13 propagating in a transmission line 11. By controlling controllable impedance elements 14, which are arranged along the transmission line 11, the parametric coupling can be achieved and controlled. In particular, the impedance modulations can be controlled with respectively associated phases, such that the parametric coupling of propagating electromagnetic waves 13 only occurs in one direction of propagation and not the reverse, hence making the transmission line 11 non-reciprocal, which allows building an isolator device. Additionally, dispersion engineering may be used to ensure phase mismatching to lower frequency modes and achieve higher isolation.

In the claims as well as in the description of this disclosure, the word “comprising” does not exclude other elements or steps and the indefinite article “a” or “an” does not exclude a plurality. A single element may fulfill the functions of several entities or items recited in the claims. The mere fact that certain measures are recited in the mutual different dependent claims does not indicate that a combination of these measures cannot be used in an implementation.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A device for broadband isolation in a bandwidth of interest, the device comprising:
a transmission line having a set of electromagnetic modes supporting propagation of electromagnetic waves, the set of electromagnetic modes including a first subset of modes in the bandwidth of interest and a second subset of modes outside of the bandwidth of interest, wherein the transmission line comprises a multitude of controllable impedance elements distributed along the transmission line; and
a controller configured to control the controllable impedance elements to generate a set of impedance modulations in the transmission line, the impedance modulations producing new tones in a spectrum of the electromagnetic waves propagating in the transmission line, wherein the controller is configured to control the controllable impedance elements to generate the set of impedance modulations with a particular set of associated phases, such that:
for a first direction of propagation of electromagnetic waves supported by the first subset of modes of the transmission line, the new tones constructively interfere and lead to parametric coupling from the first subset of modes to the second subset of modes, and
for an opposite second direction of propagation of the electromagnetic waves supported by the first subset of modes in the transmission line, the new tones destructively interfere and prevent parametric coupling from the first subset of modes to the second subset of modes; and
wherein the transmission line is further designed such that the set of electromagnetic modes includes a third subset of modes at lower frequencies than the first and second subsets of modes, and such that a phase mismatch between the third subset of modes and the first and second subsets of modes prevents parametric coupling from the first and second subsets of modes to the third subset of modes.

2. The device according to claim 1, wherein
the phase mismatch that prevents the parametric coupling from the first and second subsets of modes to the third subset of modes is a phase shift in a dispersion relation of the transmission line between the first and second subsets of modes and the third subset of modes.

3. The device according to claim 1, further comprising a multitude of capacitive or inductive elements, which are distributed along and connected to the transmission line, configured to generate the phase mismatch.

4. The device according to claim 3,
wherein the transmission line comprises a multitude of consecutively arranged unit cells, each unit cell comprising an inductive element, which is connected in series with the inductive elements of the other unit cells, and a shunt capacitive element to ground; and
wherein the multitude of capacitive or inductive elements comprises a multitude of shunt inductive elements to ground, wherein each unit cell comprises one shunt inductive element.

5. The device according to claim 3,
wherein the transmission line comprises a multitude of consecutively arranged unit cells, each unit cell comprising an inductive element, which is connected in series with the inductive elements of the other unit cells, and a shunt capacitive element to ground; and
wherein the multitude of capacitive or inductive elements comprises a plurality of shunt inductive elements to ground, wherein only each unit cell of a subset of the unit cells comprises a shunt inductive element.

6. The device according to claim 3,
wherein the transmission line comprises a multitude of consecutively arranged unit cells, each unit cell comprising an inductive element, which is connected in series with the inductive elements of the other unit cells, and a shunt capacitive element to ground; and
wherein the multitude of capacitive or inductive elements comprises a multitude of resonant elements, wherein each unit cell comprises one resonant element, which is connected in series with the inductive and resonant elements of the other unit cells.

7. The device according to claim 3,
wherein the transmission line comprises a multitude of consecutively arranged unit cells, each unit cell comprising an inductive element, which is connected in series with the inductive elements of the other unit cells, and a shunt capacitive element to ground; and
wherein the multitude of capacitive or inductive elements comprises a plurality of resonant elements, wherein only each unit cell of a subset of the unit cells comprises a resonant element in series with the inductive elements of the other unit-cells.

8. The device according to claim 3,
wherein the transmission line comprises a multitude of consecutively arranged unit cells, each unit cell comprising an inductive element, which is connected in series with the inductive elements of the other unit cells, and a shunt capacitive element to ground; and
wherein the multitude of capacitive or inductive elements comprises a multitude of resonant elements, wherein each unit cell comprises one resonant element, which is connected in parallel with the shunt capacitive element to ground.

9. The device according to claim 3,
wherein the transmission line comprises a multitude of consecutively arranged unit cells, each unit cell comprising an inductive element, which is connected in series with the inductive elements of the other unit cells, and a shunt capacitive element to ground; and
wherein the multitude of capacitive or inductive elements comprises a plurality of resonant elements, wherein only each unit cell of a subset of the unit cells comprises a resonant element in parallel with the shunt capacitive element to ground.

10. The device according to claim 1, wherein the parametric coupling from the first subset of modes to the second subset of modes comprises adiabatic mode conversion from the first subset of modes to the second subset of modes.

11. The device according to claim 1, wherein the multitude of controllable impedance elements comprises more than 100 controllable impedance elements, which are distributed along the transmission line for enabling an adiabatic mode conversion from the first subset of modes to the second subset of modes.

12. The device according to claim 1, wherein:
a distance between adjacent controllable impedance elements of the multitude of controllable impedance elements varies along the transmission line; or
a size of or an area occupied by a respective controllable impedance element of the multitude of controllable impedance elements varies along the transmission line.

13. The device according to claim 1, wherein the multitude of controllable impedance elements comprises one of:
superconducting quantum interference devices configured to be modulated by a set of external flux as a pump signal;
voltage-controlled capacitors configured to be modulated by a set of external voltages as a pump signal; or
Josephson junctions, kinetic inductances, a material with second or third order nonlinearity, or any other nonlinear elements configured to be impedance modulated by a pump signal.

14. The device according to claim 13, wherein the controller is configured to cause an adiabatic mode conversion from the first subset of modes to the second subset of modes by spatially varying the phase-mismatch or the amplitude of the modulations.

15. The device according to claim 1, further comprising
an additional transmission line extending next to the transmission line,
wherein the multitude of controllable impedance elements are connected to the additional transmission line, and
wherein the controller is configured to control the controllable impedance elements by generating a pump signal on the additional transmission line.

16. The device according to claim 15, wherein:
the controller is configured to generate the pump signal on the additional transmission line to modulate a voltage across each of a multitude of varactors being the controllable impedance elements, in order to generate the set of impedance modulations; or
the controller is configured to generate the pump signal on the additional transmission line to modulate magnetic fluxes threading the multitude of SQUIDs being the controllable impedance elements, in order to generate the set of impedance modulations.

17. The device according to claim 1, wherein the controller is configured to control the controllable impedance elements to generate the set of impedance modulations at a first frequency and with an associated set of phases, to realize nonreciprocal adiabatic conversion between electromagnetic waves supported by the first subset of modes and propagating in the first direction of propagation and electromagnetic waves supported by the second subset of modes and propagating in the same first direction of propagation.

18. The device according to claim 1, wherein:
the electromagnetic waves are radio frequency, RF, waves or RF noise; or
the electromagnetic waves are optical waves or optical noise.

19. The device according to claim 1, wherein the transmission line is an optical waveguide or a RF transmission line.

20. A method of operating a device for broadband isolation in a bandwidth of interest
according to claim 1, the method comprising:
propagating electromagnetic waves supported by the first subset of modes of the transmission line in the first direction or in the opposite second direction;
controlling the multitude of controllable impedance elements, which are distributed along the transmission line, to generate the set of impedance modulations in the transmission line;
wherein the controllable impedance elements are controlled to generate the set of impedance modulations with a particular set of associated phases, such that
for the first direction of propagation of the electromagnetic waves supported by the first subset of modes, the new tones constructively interfere and lead to parametric coupling from the first subset of modes to the second subset of modes, and
for the opposite second direction of propagation of the electromagnetic waves supported by the first subset of modes, the new tones destructively interfere and prevent parametric coupling from the first subset of modes to the second subset of modes.
